(19) United States
(12) Patent Application Publication
(10) Pub. No.: US 2026/0068342 A1
(43) Pub. Date: Mar. 5, 2026

(54) LIGHT RECEIVING ELEMENT AND LIGHT DETECTION DEVICE

(71) Applicant: SONY SEMICONDUCTOR SOLUTIONS CORPORATION, KANAGAWA (JP)

(72) Inventor: Haruyuki NAKAGAWA, KANAGAWA (JP)

(21) Appl. No.: 19/100,907

(22) PCT Filed: Aug. 9, 2022
(86) PCT No.: PCT/JP2022/030461

§ 371 Date: Feb. 3, 2025

(51) Int. Cl. H10F 39/00

(52) U.S. Cl. CPC H10F 39/8057; H10F 39/809; H10F 39/811

(57) ABSTRACT

Provided is a light receiving element capable of enhancing accuracy of measurement of color mixing components contained in output signals of light shielding pixels located around a light receiving pixel. A peripheral pixel region has a specific pixel group including a light receiving pixel and light shielding pixels surrounding the light receiving pixel. A first conductivity type region corresponding to the light receiving pixel and the light shielding pixels of the specific pixel group is made lower in concentration of a first conductivity type impurity than a first conductivity type region corresponding to an effective pixel located in an effective pixel region. Since the concentration of the first conductivity type impurity of the specific pixel group (the light receiving pixel and the light shielding pixels) is low, it is possible to weaken a pn junction strength and suppress dark current in the light receiving pixel and the light shielding pixels. It is therefore possible to reduce noise contained in the output signals of the light shielding pixels and enhance the accuracy of measurement of the color mixing components included in the output signals of the light shielding pixels.

### TECHNICAL FIELD

The present disclosure relates to a light receiving element and a light detection device.

### BACKGROUND ART

In the related art, there has been proposed a light receiving element including a plurality of pixels each having a photoelectric converter including a silicon semiconductor, and pixels in a region outside an effective pixel region among the plurality of pixels include light shielding pixels and light receiving pixels with all adjacent pixels being light shielding pixels (see, for example, Patent Document 1). In the light receiving element disclosed in Patent Document 1, a color mixing component contained in an output signal of the light shielding pixel is measured, and an output signal of an effective pixel is corrected on the basis of the measurement result.

### CITATION LIST

### Patent Document

Patent Document 1: Japanese Patent Application Laid-Open No. 2011-66801

### SUMMARY OF THE INVENTION

### Problems to be Solved by the Invention

In a case where the technology disclosed in Patent Document 1 is directly applied to a light receiving element having a photoelectric converter including a compound semiconductor, however, accuracy of measurement of the color mixing component decreases, and there is a possibility that image quality of a captured image is not enhanced as expected even if the output signal of the effective pixel is corrected on the basis of the measurement result.

It is therefore an object of the present disclosure to provide a light receiving element and a light detection device capable of enhancing accuracy of measurement of a color mixing component contained in an output signal of a light shielding pixel.

### Solutions to Problems

A light receiving element of the present disclosure includes: (a) a plurality of pixels having a common photoelectric conversion layer including a compound semiconductor; and (b) a contact layer arranged on a surface of the photoelectric conversion layer opposite to a light incident surface, in which (c) the contact layer includes a plurality of first conductivity type regions formed on a one-to-one basis with respect to the plurality of pixels, and a second conductivity type region that is a region other than the first conductivity type region, and (d) a peripheral pixel region located outside an effective pixel region in a pixel region where the pixels are arranged includes a specific pixel group including a light receiving pixel and a light shielding pixel arranged to surround the light receiving pixel, the first conductivity type region corresponding to the light receiving pixel and the light shielding pixel of the specific pixel group being lower in concentration of a first conductivity type impurity than the first conductivity type region corresponding to an effective pixel located in the effective pixel region.

A light detection device of the present disclosure includes: a light receiving element including (a) a plurality of pixels having a common photoelectric conversion layer including a compound semiconductor, and (b) a contact layer arranged on a surface of the photoelectric conversion layer opposite to a light incident surface, (c) the contact layer including a plurality of first conductivity type regions formed on a one-to-one basis with respect to the plurality of pixels, and a second conductivity type region that is a region other than the first conductivity type region, (d) a peripheral pixel region located outside an effective pixel region in a pixel region where the pixels are arranged including a specific pixel group including a light receiving pixel and light shielding pixel arranged to surround the light receiving pixel, the first conductivity type region corresponding to the light receiving pixel and the light shielding pixel of the specific pixel group being lower in concentration of a first conductivity type impurity than the first conductivity type region corresponding to effective pixels located in the effective pixel region; (e) a color mixing parameter generation unit that generates, on the basis of output signals of the light receiving pixel and the light shielding pixels of the specific pixel group, color mixing parameters for reducing an impact of charges transferred from another one of the effective pixels from an output signal of each of the effective pixels located in the effective pixel region of the light receiving element; and (f) an output signal correction unit that corrects the output signal of each of the effective pixels in accordance with the color mixing parameters generated by the color mixing parameter generation unit.

### BRIEF DESCRIPTION OF DRAWINGS

FIG. 1 is a diagram illustrating a schematic configuration of an imaging device according to a first embodiment.

FIG. 2 is a diagram illustrating a planar configuration of a light receiving element.

FIG. 3 is a diagram illustrating a cross-sectional configuration of a light receiving element in an effective pixel region, taken along line A-A in FIG. 2.

FIG. 4 is an enlarged view of a region B in FIG. 2, illustrating a planar configuration of a specific pixel group in a peripheral pixel region.

FIG. 5 is a diagram illustrating a light receiving pixel and a light shielding pixel, taken along line C-C in FIG. 4.

FIG. 6 is a diagram illustrating an OPB pixel, taken along line D-D in FIG. 4.

FIG. 7 is a diagram illustrating a color mixing parameter, and a light receiving pixel and a light shielding pixel in a superimposed manner.

FIG. 8 is a diagram showing concentration distribution of a first conductivity type impurity in a first conductivity type region.

FIG. 9 is a diagram for describing an internal configuration of a digital signal processing unit.

FIG. 10 is a diagram illustrating a method for correcting a captured image signal by using an output signal correction unit.

FIG. 11 is a diagram illustrating a method for correcting a captured image signal by using the output signal correction unit.

FIG. 12 is a diagram illustrating a planar configuration of a specific pixel group according to a modification.

FIG. 13 is a diagram illustrating a planar configuration of a specific pixel group according to a modification.

FIG. 14 is a diagram illustrating a planar configuration of a light receiving element and a specific pixel group according to a modification.

FIG. 15 is a diagram for describing an internal configuration of a digital signal processing unit according to a modification.

FIG. 16 is a diagram illustrating a cross-sectional configuration of a light receiving element in an effective pixel region according to a modification.

FIG. 17 is a diagram illustrating a cross-sectional structure of an element substrate in an effective pixel region according to a modification.

FIG. 18 is a diagram illustrating a cross-sectional configuration of a light receiving pixel in a peripheral pixel region according to a modification.

FIG. 19 is a diagram illustrating a cross-sectional configuration of a light shielding pixel in a peripheral pixel region according to a modification.

### MODE FOR CARRYING OUT THE INVENTION

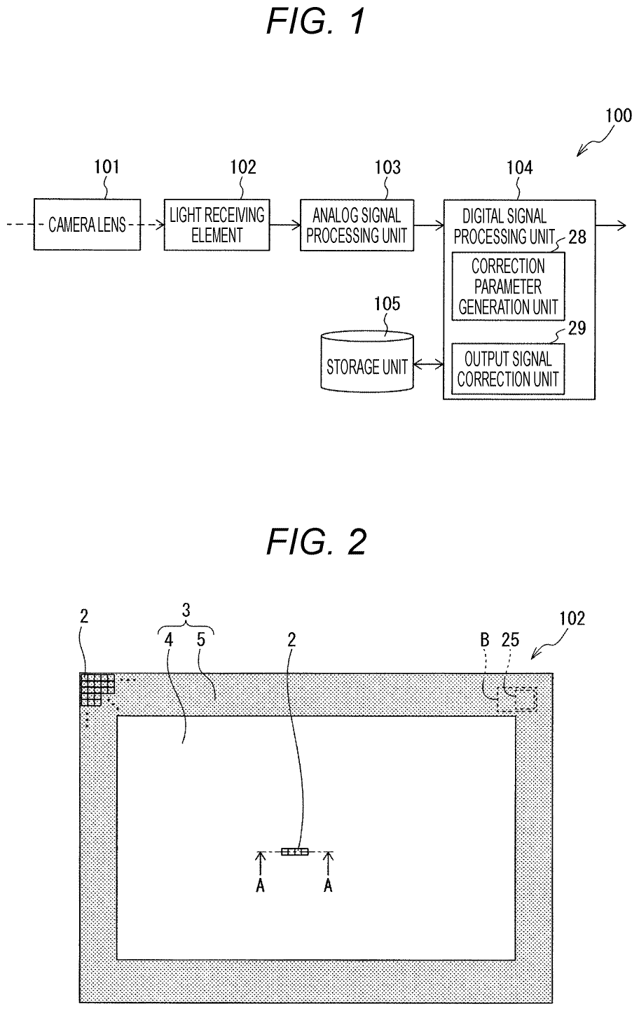

Hereinafter, examples of a light receiving element and a light detection device according to embodiments of the present disclosure will be described with reference to FIGS. 1 to 16. The embodiments of the present disclosure will be described in the following order. Note that, the present disclosure is not limited to the following examples. Furthermore, the effects described herein are illustrative and not restrictive, and there may be additional effects.
1. First Embodiment
   1-1 Configuration of imaging device
   1-2 Configuration of light receiving element
   1-3 Configuration of light receiving element in peripheral pixel region
   1-4 Configuration of digital signal processing unit
   1-5 Modification

### 1. First Embodiment

### [1-1 Configuration of Imaging Device]

An imaging device as an example of a light detection device according to a first embodiment of the present disclosure will be described.

FIG. 1 is a diagram illustrating a schematic configuration of an imaging device 100 according to the first embodiment.

As illustrated in FIG. 1, the imaging device 100 (in a broad sense, a “light detection device”) includes a camera lens 101, a light receiving element 102, an analog signal processing unit 103, a digital signal processing unit 104, and a storage unit 105. For example, the imaging device 100 is applied to an infrared camera that detects wavelengths in a visible range (for example, 380 to 780 nm) to a short infrared range (for example, 780 to 2400 nm).

The camera lens 101 guides incident light (image light) from a subject to the light receiving element 102, and forms an image on a light incident surface (an effective pixel region 4 illustrated in FIG. 2) of the light receiving element 102.

The light receiving element 102 converts, for each pixel, intensity of the incident light, which has been formed into an image on the effective pixel region 4 by the camera lens 101, into an electrical signal. The electrical signal resulting the conversion is supplied to the analog signal processing unit 103 as an output signal. A detailed configuration of the light receiving element 102 will be described later.

The analog signal processing unit 103 performs processing such as sample-and-hold and automatic gain control on the output signal supplied from the light receiving element 102, and then performs analog-digital (A/D) conversion. The output signal of the effective pixel region 4 resulting from the A/D conversion is supplied to the digital signal processing unit 104 as a captured image signal. Furthermore, an output signal of a peripheral pixel region 5 is also supplied to the digital signal processing unit 104.

The digital signal processing unit 104 performs signal processing such as white balance processing, gamma processing, and color difference signal processing on the captured image signal and the like supplied from the analog signal processing unit 103. For example, a digital signal processor (DSP) circuit can be employed.

The storage unit 105 stores various parameters and the like used in the digital signal processing unit 104. For example, a flash memory or the like can be employed as the storage unit 105.

Next, the configurations of light receiving element 102 and digital signal processing unit 104 will be described.

### [1-2 Configuration of Light Receiving Element]

Next, the configuration of the light receiving element 102 will be described.

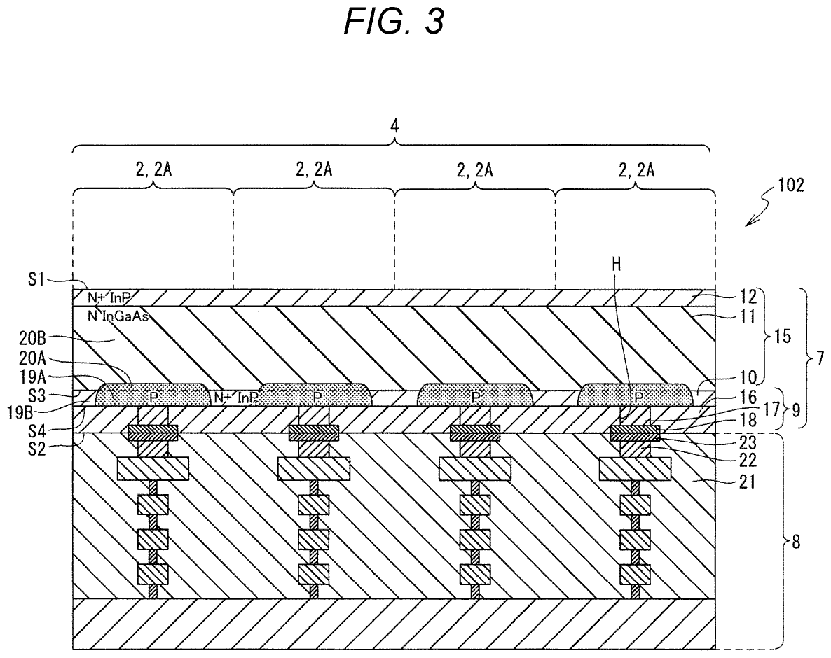

FIG. 2 is a diagram illustrating a planar configuration of the light receiving element 102. Furthermore, FIG. 3 is a diagram illustrating a cross-sectional configuration of the light receiving element 102 in the effective pixel region 4, taken along line A-A in FIG. 2. The light receiving element 102 in FIG. 3 includes a pixel region 3 in which a plurality of pixels 2 is arranged in a two-dimensional array, and has, for example, a function of photoelectrically converting light having a wavelength in a visible to short infrared range.

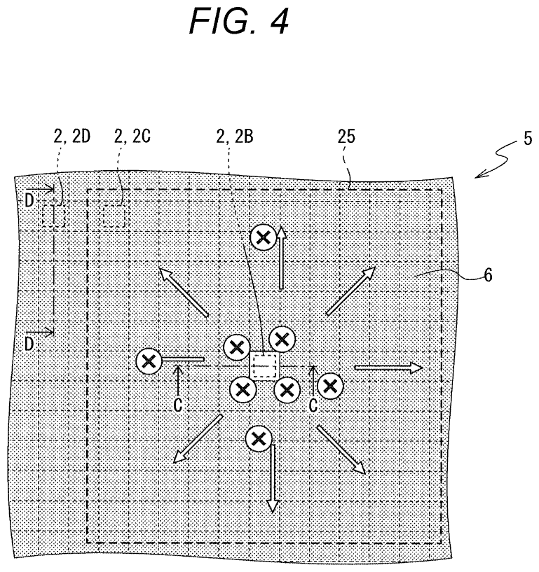

As illustrated in FIG. 2, the pixel region 3 includes the effective pixel region 4 located in a central part, and the peripheral pixel region 5 that is a region located outside the effective pixel region 4 to surround the effective pixel region 4. A light shielding film 6 (see FIG. 4) is formed on a light incident surface of the pixel region 3 (in FIG. 2, the front side of the paper). The light shielding film 6 has an opening in a region where the effective pixel region 4 and a light receiving pixel 2B are located. Examples of the material of the light shielding film 6 include titanium (Ti), tungsten (W), carbon (C), chromium oxide (Cr₂O₃), an alloy of samarium (Sm) and silver (Ag), and an organic material.

The effective pixel region 4 corresponds to a region where the image of the subject is formed. As illustrated in FIG. 3, in the effective pixel region 4, the light receiving element 102 has a multilayer structure formed by stacking an element substrate 7 and a readout circuit substrate 8. Here, the element substrate 7 has one surface serving as a light incident surface (hereinafter, also referred to as “back surface S1”) and has the other surface serving as a junction surface (hereinafter, also referred to as “front surface S2”) with the readout circuit substrate 8. The element substrate 7 includes a wiring layer 9, a first contact layer 10 (in a broad sense, a “contact layer”), a photoelectric conversion layer 11, and a second contact layer 12 in this order from the readout circuit substrate 8. The first contact layer 10, the photoelectric conversion layer 11, and the second contact layer 12 constitute a semiconductor layer 15. Furthermore, the readout circuit substrate 8 is a so-called readout integrated circuit (ROIC), and is arranged so as to be in contact with the junction surface (front surface S2) of the element substrate 7.

The wiring layer 9 is formed across the entire effective pixel region 4 and has the junction surface (front surface S2) with the readout circuit substrate 8. The wiring layer 9 includes an electrode 17 in an interlayer insulating film 16. The interlayer insulating film 16 includes, for example, an inorganic insulating material. Examples of the inorganic insulating material include silicon nitride (SiN), aluminum oxide (Al₂O₃), silicon oxide (SiO₂), and hafnium oxide (HfO₂). Furthermore, in the wiring layer 9, an opening H is formed for each pixel 2 (for each first conductivity type region 19A).

Furthermore, the electrode 17 is embedded in the opening H of the wiring layer 9, and has an end adjacent to the first contact layer 10 connected to the first conductivity type region 19A of the first contact layer 10. As the material of the electrode 17, for example, any one of titanium (Ti), tungsten (W), titanium nitride (TiN), platinum (Pt), gold (Au), germanium (Ge), palladium (Pd), zinc (Zn), nickel (Ni), or aluminum (Al), or an alloy containing at least one of them can be employed. This allows the electrode 17 to electrically connect to a tip portion of the first conductivity type region 19A present in the photoelectric conversion layer 11 (that is, a first conductivity type region 20A of the photoelectric conversion layer 11) through a root portion of the first conductivity type region 19A located in the first contact layer 10. Then, a voltage is applied to the photoelectric conversion layer 11 for reading out charges (for example, holes) generated in the photoelectric conversion layer 11.

Furthermore, an eaves-like connection layer 18 (metal pad) extending in a radial direction of the electrode 17 is formed at an end of the electrode 17 adjacent to the readout circuit substrate 8. The connection layer 18 is a metal pad bonded to a connection layer 23 of the readout circuit substrate 8 so as to electrically connect the electrode 17 to a readout electrode 22 of the readout circuit substrate 8. As the material of the connection layer 18, for example, copper (Cu) can be employed.

The first contact layer 10 is a layer constituting the front surface of the semiconductor layer 15, and is arranged on a surface (hereinafter, also referred to as “surface S3”) of the photoelectric conversion layer 11 opposite to the light incident surface. As the material of the first contact layer 10, for example, a compound semiconductor larger in band gap than the photoelectric conversion layer 11 can be employed. For example, in a case where the photoelectric conversion layer 11 includes In_{0.53}Ga_{0.47}As (band gap 0.74 eV), examples of the compound semiconductor larger in band gap than In_{0.53}Ga_{0.47}As include InP (band gap 1.34 eV).

Furthermore, the first contact layer 10 includes a plurality of the first conductivity type regions 19A formed on a one-to-one basis with respect to the pixels 2. That is, the plurality of first conductivity type regions 19A is formed discretely in the first contact layer 10. As the first conductivity type impurity contained in the first conductivity type region 19A, for example, a p-type impurity can be employed. Examples of the impurity include zinc (Zn). The first conductivity type region 19A extends from a surface (hereinafter, also referred to as “surface S4”) of the first contact layer 10 adjacent to the readout circuit substrate 8 into the photoelectric conversion layer 11, and the tip portion of the first conductivity type region 19A constitutes the first conductivity type region 20A of the photoelectric conversion layer 11.

Furthermore, the first contact layer 10 includes a second conductivity type region 19B that is a region other than first conductivity type region 19A. That is, the second conductivity type region 19B is formed around the first conductivity type region 19A in the first contact layer 10 so as to be in contact with the first conductivity type region 19A. As the second conductivity type impurity contained in the second conductivity type region 19B, for example, an n-type impurity can be employed. With such a configuration, it is possible for the first contact layer 10 to form a pn junction interface between the first conductivity type region 19A and the second conductivity type region 19B and electrically isolate adjacent pixels 2.

The photoelectric conversion layer 11 is formed as a common layer for the plurality of pixels 2. That is, one photoelectric conversion layer 11 is formed for all the pixels 2. As the material of the photoelectric conversion layer 11, for example, a compound semiconductor such as a group III-V semiconductor can be employed. For example, indium gallium arsenide (InGaAs), indium gallium nitride (InGaN), indium aluminum nitride (InAlN), indium arsenide antimony (InAsSb), indium arsenide (InAs), indium antimony (InSb), or mercury cadmium telluride (HgCdTe) can be employed. Furthermore, examples of InGaAs include InₓGa₍₁₋ₓ₎As (0<x≤1). In particular, in order to achieve sensitivity in the infrared region, x≥0.4 is desirable. For example, in a case where the second contact layer 12 includes InP, examples of the composition of the compound semiconductor of the photoelectric conversion layer 11 include In_{0.53}Ga_{0.47}As lattice-matched with InP. Note that, as the material of the photoelectric conversion layer 11, not only an inorganic semiconductor but also an organic semiconductor can be employed.

The photoelectric conversion layer 11 includes the first conductivity type region 20A formed for each pixel 2 on a surface (surface S3) opposite to the light incident surface of the photoelectric conversion layer 11, and a part other than the first conductivity type region 20A (hereinafter, also referred to as “second conductivity type region 20B”). The first conductivity type region 20A includes the tip portion of the first conductivity type region 19A of the first contact layer 10. As the first conductivity type impurity contained in the first conductivity type region 20A and the second conductivity type impurity contained in the second conductivity type region 20B, for example, the same impurities as those contained in the first conductivity type region 19A and the second conductivity type region 19B can be employed, respectively. With such a configuration, the photoelectric conversion layer 11 forms a photodiode by using a pn junction, and photoelectrically converts light having a wavelength in a visible to short infrared range to generate charges (holes).

The second contact layer 12 includes, for example, a compound semiconductor such as a group III-V semiconductor containing the second conductivity type impurity. Examples of the compound semiconductor include n-type InP. With such a configuration, the second contact layer 12 functions as a barrier layer that prevents backflow of charges generated in the photoelectric conversion layer 11.

The readout circuit substrate 8 is bonded to the junction surface (front surface S2) of the element substrate 7. The readout circuit substrate 8 includes the readout electrode 22 in an interlayer insulating film 21. Furthermore, an eaves-like connection layer 23 (metal pad) extending in a radial direction of the readout electrode 22 is formed at an end of the readout electrode 22 adjacent to the element substrate 7. As the material of the connection layer 23, for example, copper (Cu) can be employed. The connection layer 27 is Cu—Cu bonded to the connection layer 18 (metal pad) of the element substrate 7 to electrically connect the readout electrode 22 of the readout circuit substrate 8 to the electrode 17 of the element substrate 7. Such a configuration allows the readout circuit substrate 8 to read out charges (holes) generated in the photoelectric conversion layer 11 for each pixel 2.

Note that, in the first embodiment, the example has been described where the element substrate 7 and the readout circuit substrate 8 are Cu—Cu bonded, but other configurations can also be employed. For example, bump bonding may be used.

### [1-3 Configuration of Light Receiving Element in Peripheral Pixel Region]

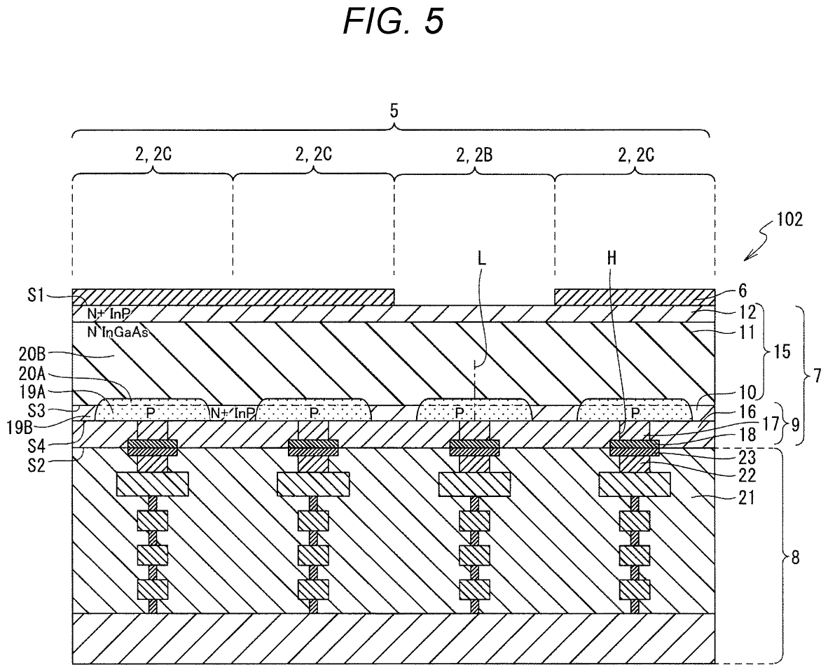

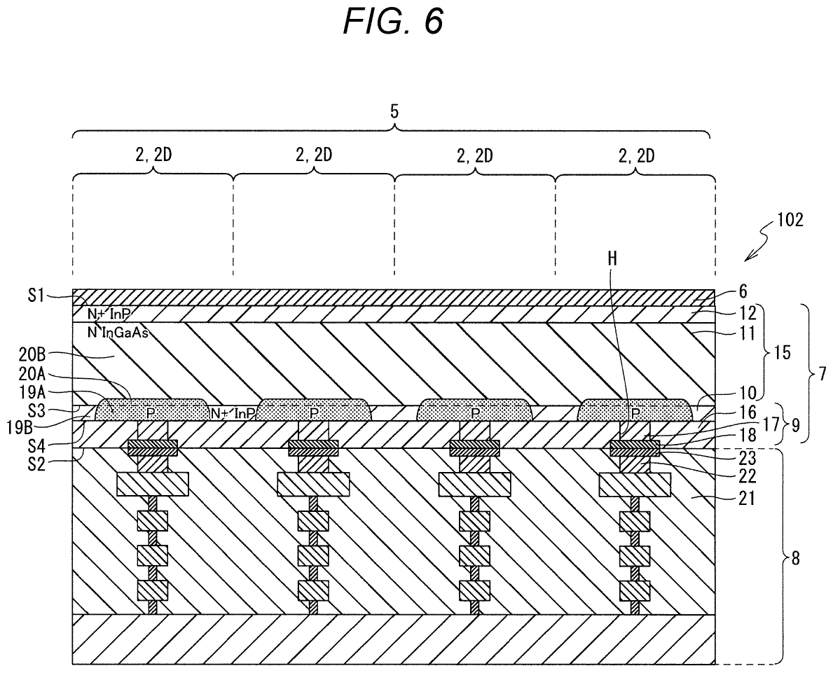

FIG. 4 is an enlarged view of a region B in FIG. 2, illustrating a planar configuration of a specific pixel group 25 in the peripheral pixel region 5. FIGS. 5 and 6 are diagrams each illustrating a cross-sectional configuration of the light receiving element 102 in the peripheral pixel region 5, FIG. 5 is a diagram illustrating the light receiving pixel 2B and a light shielding pixel 2C taken along line C-C in FIG. 4, and FIG. 6 is a diagram illustrating an OPB pixel 2D taken along line D-D in FIG. 4.

The peripheral pixel region 5 is a region surrounding the effective pixel region 4. As illustrated in FIGS. 5 and 6, in the peripheral pixel region 5, the light receiving element 102 has layers (the light shielding film 6, the wiring layer 9, the first contact layer 10, the photoelectric conversion layer 11, and the second contact layer 12) similar to those in the effective pixel region 4.

The peripheral pixel region 5 includes a light receiving pixel 2B and light shielding pixels 2C arranged to surround the light receiving pixel 2B. The light receiving pixel 2B is a pixel where the surface S4 of the photoelectric conversion layer 11 is not covered with the light shielding film 6. Furthermore, each of the light shielding pixels 2C is a pixel where the back surface S1 of the second contact layer 12 is covered with the light shielding film 6. Furthermore, the light receiving pixel 2B and the plurality of light shielding pixels 2C surrounding the light receiving pixel 2B constitute the specific pixel group 25. FIG. 4 illustrates a case where the specific pixel group 25 includes one light receiving pixel 2B and a plurality of light shielding pixels 2C surrounding the one light receiving pixel 2B. More specifically, in FIG. 4, as the specific pixel group 25, the light receiving pixel 2B and the light shielding pixels 2C are arranged in a two-dimensional array of 11×11.

As described above, with the configuration including the specific pixel group 25 including the light receiving pixel 2B and the light shielding pixels 2C, when light is incident on the light receiving pixel 2B, a part of the photoelectric conversion layer 11 constituting the light receiving pixel 2B photoelectrically converts the light to generate charges (holes). Most of the generated charges are read out by the readout circuit substrate 8 via the first conductivity type region 19A of the light receiving pixel 2B. At the same time, some of the generated charges moves in the photoelectric conversion layer 11, enters a part of the photoelectric conversion layer 11 constituting the light shielding pixel 2C, and is read out by the readout circuit substrate 8 via the first conductivity type region 19A of the light shielding pixel 2C. Therefore, an output signal of the light shielding pixel 2C corresponds to a signal (hereinafter, also referred to as “color mixing component”) based on charges generated due to crosstalk where charges resulting from the photoelectric conversion in the light receiving pixel 2B move to the light shielding pixel 2C. With such a configuration, it is possible to simulate the spread of charges from a certain effective pixel 2A to surrounding effective pixels 2A, which occurs in the effective pixel region 4, by using the light receiving pixel 2B and the light shielding pixel 2C.

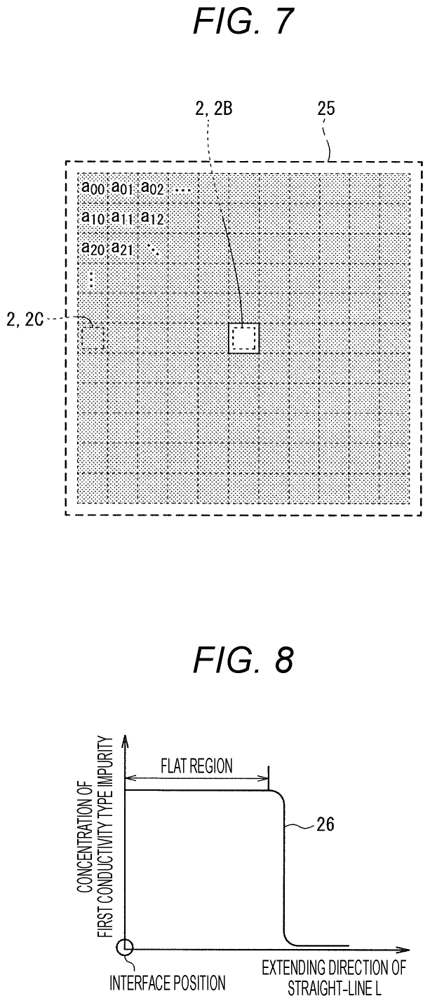

Therefore, on the basis of the output signals read from the specific pixel group 25 (the light receiving pixel 2B and the light shielding pixels 2C), values resulting from dividing the respective output signals of the light shielding pixels 2C by the output signal of the light receiving pixel 2B can be acquired as color mixing parameters a₀₀, a₀₁, a₀₂ . . . (see FIG. 7) by the digital signal processing unit 104 and the like. The color mixing parameters a₀₀, a₀₁, a₀₂ . . . correspond to parameters representing how much charges spread from the central light receiving pixel 2B to the surrounding light shielding pixels 2C. Furthermore, the color mixing parameters a₀₀, a₀₁, a₀₂ . . . also correspond to parameters used to reduce an impact, on the output signal of each pixel 2 located in the effective pixel region 4 of the light receiving element 102 (hereinafter, also referred to as “effective pixel 2A”), of charges moved from another effective pixel 2A. FIG. 7 illustrates a case where the color mixing parameters a₀₀, a₀₁, a₀₂ . . . , the light receiving pixel 2B, and the light shielding pixels 2C are shown in a superimposed manner so as to make their relationship clear. Furthermore, a matrix in which the color mixing parameters a₀₀, a₀₁, a₀₂ . . . are arranged in the array illustrated in FIG. 7 is referred to as “color mixing matrix C”.

Here, a compound semiconductor such as InGaAs is prone to generating dark current, and the magnitude of the dark current tends to be large. Therefore, in a case where the photoelectric conversion layer 11 includes a compound semiconductor, noise contained in the output signal of the light shielding pixel 2C tends to be large. Therefore, in a case where the color mixing component contained in the output signal of the light shielding pixel 2C is measured, there is a possibility that the accuracy of measurement of the color mixing component decreases.

On the other hand, in the first embodiment, the first conductivity type region 19A corresponding to the light receiving pixel 2B and the light shielding pixel 2C of the specific pixel group 25 is made lower in concentration of the first conductivity type impurity than the first conductivity type region 19A corresponding to the effective pixel 2A located in the effective pixel region 4. Therefore, since the specific pixel group 25 (the light receiving pixel 2B and the light shielding pixel 2C) is lower in concentration of the first conductivity type impurity, the pn junction strength can be reduced, and the dark current in the light receiving pixel 2B and the light shielding pixel 2C can be suppressed. It is therefore possible to reduce noise contained in the output signal of the light shielding pixel 2C, and enhance the accuracy of measurement of the color mixing component contained in the output signal of the light shielding pixel 2C. Then, since the effective pixel region 4 remains high in concentration of the first conductivity type impurity, the pn junction strength can be increased, the saturation charge amount of the effective pixel 2A does not decrease, and deterioration in image quality of the captured image obtained from the light receiving element 102 can be suppressed.

Furthermore, in the first embodiment, as illustrated in FIGS. 5 and 8, concentration distribution 26 of the first conductivity type impurity in the first conductivity type region 19A on a straight-line L extending from the interface S4 between the first conductivity type region 19A and the electrode 17 toward the light incident surface of the photoelectric conversion layer 11 has a flat region from the interface S4 to a predetermined depth in the extending direction of the straight-line L. Therefore, the above-described condition for the concentration of the first conductivity type impurity can be rephrased as, for example, that an average concentration X of the flat region of the concentration distribution 26 for the first conductivity type region 19A corresponding to the light receiving pixel 2B and the light shielding pixel 2C of the specific pixel group 25 is lower than an average concentration Y of the flat region of the concentration distribution 26 for the first conductivity type region 19A corresponding to the effective pixel 2A located in the effective pixel region 4 (X<Y). As the flat region, for example, a range from the interface S4 to a depth of 50 nm can be employed.

Furthermore, as illustrated in FIGS. 4 and 5, the peripheral pixel region 5 includes the optical black (OPB) pixel 2D that is a pixel different from the light receiving pixel 2B and the light shielding pixel 2C. The OPB pixel 2D is a pixel in which the back surface S1 of the second contact layer 12 is covered with the light shielding film 6, and is a pixel used to obtain a reference signal for optical black level. Furthermore, the first conductivity type region 19A corresponding to the OPB pixel 2D is the same in concentration of the first conductivity type impurity as the first conductivity type region 19A of the effective pixel region 4. That is, an average concentration Z of the flat region of the concentration distribution 26 (see FIG. 8) for the first conductivity type region 19A corresponding to the OPB pixel 2D is the same as the average concentration Y of the flat region of the concentration distribution 26 for the first conductivity type region 19A corresponding to the effective pixel 2A located in the effective pixel region 4 (Z=Y). It is therefore possible to reduce a difference between the dark current in the OPB pixel 2D and the dark current in the effective pixel 2A, correct the black level of the output signal of the effective pixel 2A more appropriately, and obtain an image with higher image quality.

### [1-4 Configuration of Digital Signal Processing Unit]

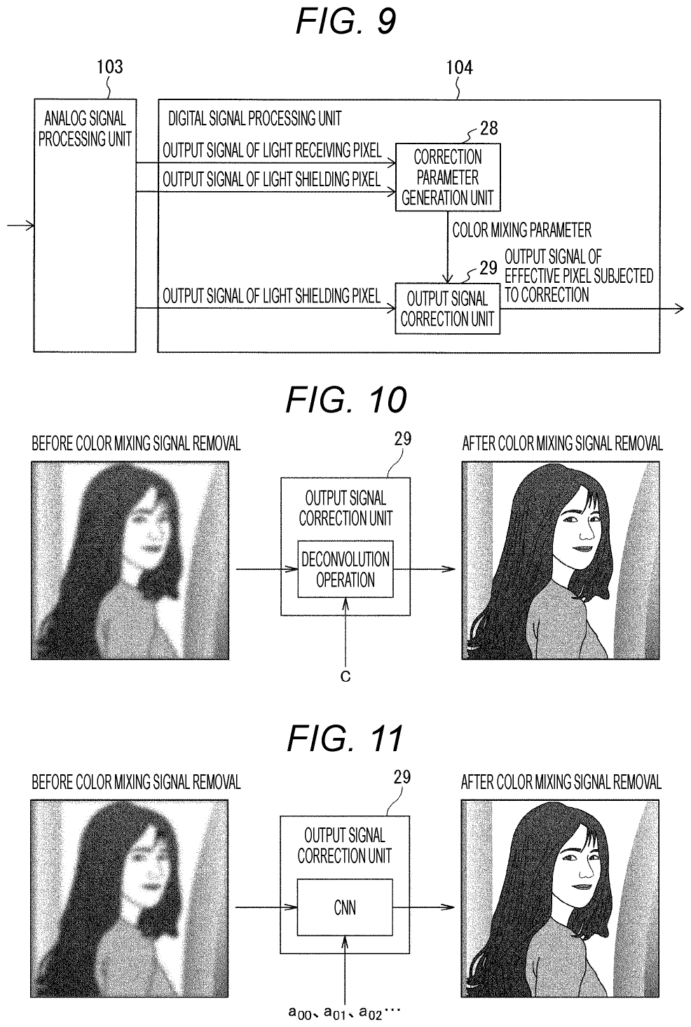

FIG. 9 is a diagram for describing an internal configuration of the digital signal processing unit 104.

As illustrated in FIGS. 1 and 9, the digital signal processing unit 104 includes a color mixing parameter generation unit 28 and an output signal correction unit 29.

The color mixing parameter generation unit 28 generates the color mixing parameters a₀₀, a₀₁, a₀₂ . . . (see FIG. 7) on the basis of the output signals of the light receiving pixel 2B and the light shielding pixels 2C of the specific pixel group 25. As a method for generating the color mixing parameters a₀₀, a₀₁, a₀₂ . . . , for example, a method can be employed in which values resulting from dividing the respective output signals of the light shielding pixels 2C by the output signal of the light receiving pixel 2B are used as the color mixing parameters a₀₀, a₀₁, a₀₂ . . . . That is, ratios of the magnitudes of the output signals of the light shielding pixels 2C to the magnitude of the output signal of the light receiving pixel 2B are calculated as the color mixing parameters a₀₀, a₀₁, a₀₂ . . . . Such a configuration allows the color mixing parameter generation unit 28 to generate the color mixing parameters a₀₀, a₀₁, a₀₂ . . . in real time when the image of the subject is captured, and allows the output signal correction unit 29 to correct the output signal of the effective pixel 2A using the generated color mixing parameters a₀₀, a₀₁, a₀₂ . . . .

The output signal correction unit 29 corrects each of the output signals (captured image signal) of the effective pixels 2A located in the effective pixel region 4 of the light receiving element 102 in accordance with the color mixing parameters a₀₀, a₀₁, a₀₂ . . . . As the correction method, for example, a method can be employed in which the color mixing matrix C is generated from the color mixing parameters a₀₀, a₀₁, a₀₂ . . . , and a deconvolution operation is performed on the captured image signal based on the output signal of the effective pixel region 4 (the output of the analog signal processing unit 103) using the generated color mixing matrix C as illustrated in FIG. 10 to obtain a captured image signal from which a color mixing component has been removed. Furthermore, for example, as illustrated in FIG. 11, a method can be employed in which the color mixing parameters a₀₀, a₀₁, a₀₂ . . . and the captured image signal based on the output signal of the effective pixel region 4 (the output of the analog signal processing unit 103) are input to a neural network (for example, a convolutional neural network (CNN)) that outputs a captured image signal from which a color mixing component has been removed to obtain the captured image signal from which the color mixing component has been removed. Note that the method for correcting a captured image signal is not limited to such methods, and any method may be employed as long as the color mixing parameters a₀₀, a₀₁, a₀₂ . . . are used.

As described above, in the first embodiment, the color mixing parameter generation unit 28 generates the color mixing parameters a₀₀, a₀₁, a₀₂ . . . on the basis of the output signals of the light receiving pixel 2B and the light shielding pixels 2C of the specific pixel group 25. Furthermore, the output signal correction unit 29 corrects the respective output signals of the effective pixels 2A located in the effective pixel region 4 of the light receiving element 102 in accordance with the color mixing parameters a₀₀, a₀₁, a₀₂ . . . . It is therefore possible for each of the effective pixels 2A to reduce a color mixing component caused by movement of charges (crosstalk) from another effective pixel 2A, and it is possible to suppress deterioration in image quality of a captured image due to crosstalk.

### [1-5 Modifications]

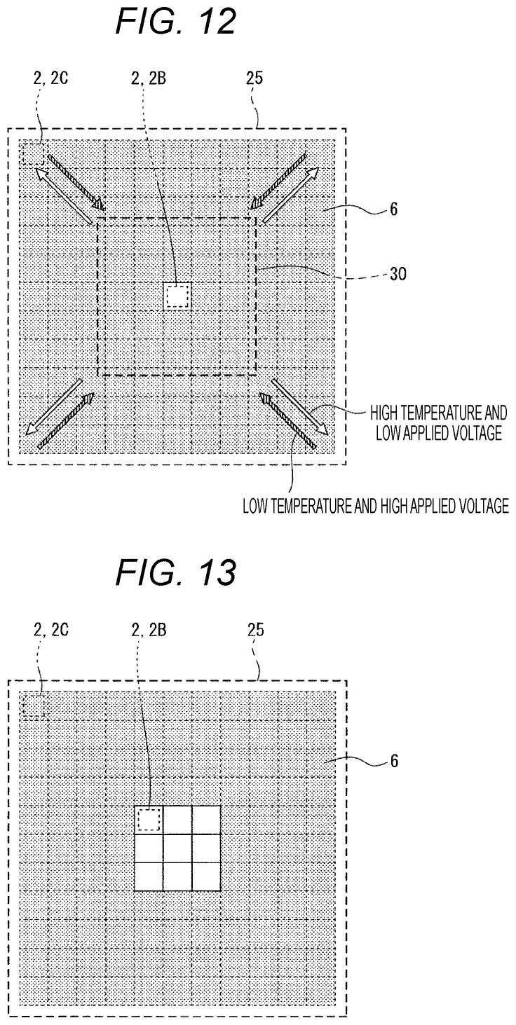

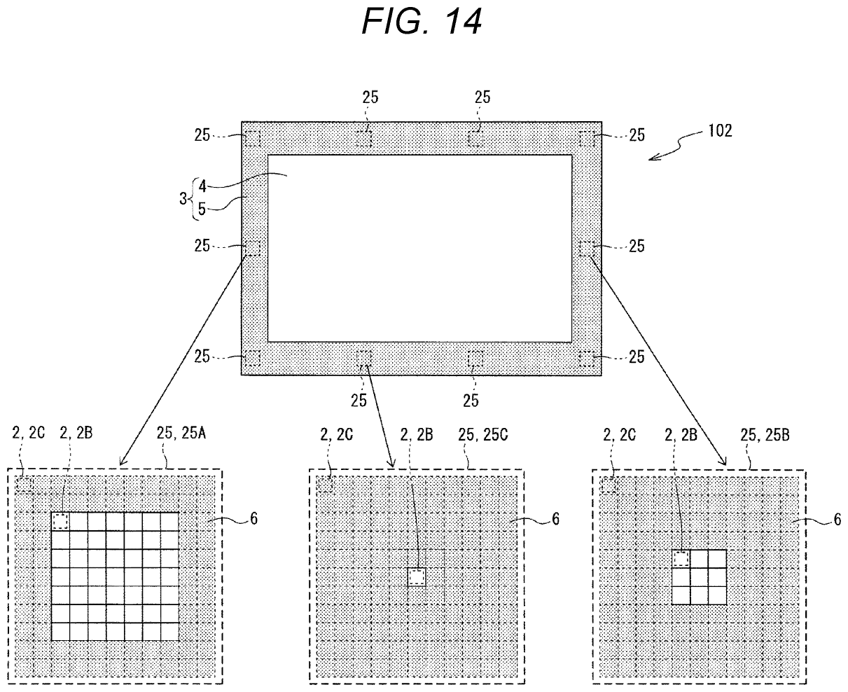

(1) Furthermore, in the first embodiment, the example has been described where the color mixing parameter generation unit 28 generates the color mixing parameters a₀₀, a₀₁, a₀₂ . . . using all the pixels of the specific pixel group 25 including the light receiving pixel 2B and the light shielding pixels 2C, but other configurations can be employed. For example, the range of the light shielding pixels 2C to be used to generate the color mixing parameters a₀₀, a₀₁, a₀₂ . . . may be set in accordance with a use environment. As the use environment, for example, a temperature of the light receiving element 102 and a voltage applied to the photoelectric conversion layer 11 can be employed. As an example, as illustrated in FIG. 12, in a case where the temperature of the light receiving element 102 is greater than or equal to a predetermined threshold, the range of the light shielding pixels 2C used to generate the color mixing parameters a₀₀, a₀₁, a₀₂ . . . is widened as compared with a case where the temperature is less than the predetermined threshold. As a method for changing the range of the light shielding pixels 2C used to generate the color mixing parameters, for example, a method can be employed in which, in a case where the range is widened, all the light shielding pixels 2C constituting the specific pixel group 25 are used, and in a case where the range is narrowed, only light shielding pixels 2C (in FIG. 12, light shielding pixels 2C in a region 30) near the light receiving pixel 2B are used. Furthermore, as another example, in a case where the voltage applied to the photoelectric conversion layer 11 is less than or equal to a predetermined threshold set in advance, the range of the light shielding pixels 2C used to generate the color mixing parameters a₀₀, a₀₁, a₀₂ . . . is widened as compared with a case where the voltage is greater than the predetermined threshold. With such methods, it is possible to generate more appropriate color mixing parameters a₀₀, a₀₁, a₀₂ . . . for a use environment (high temperature and low voltage) with a wider range of charge mobility and to more appropriately enhance the image quality of the captured image.
(2) Furthermore, in the first embodiment, the example has been described where the specific pixel group 25 includes one light receiving pixel 2B and a plurality of light shielding pixels 2C surrounding the one light receiving pixel 2B, but other configurations may be employed. For example, as illustrated in FIG. 13, a configuration where two or more light receiving pixels 2B arranged in a two-dimensional array and a plurality of light shielding pixels 2C surrounding the two or more light receiving pixels 2B may be employed. With such a configuration, it is possible to increase the total amount of charges (for example, holes) generated by the light receiving pixels 2B, simulate the spread of charges from an effective pixel 2A with higher incident light intensity to surrounding effective pixels 2A, and obtain color mixing parameters a₀₀, a₀₁, a₀₂ . . . for correcting the output signal of the effective pixel 2A with higher incident light intensity. It is therefore possible to more appropriately correct the output signal of the effective pixel 2A with higher incident light intensity.
(3) Furthermore, in the first embodiment, the example has been described where the peripheral pixel region 5 includes only one specific pixel group 25, but other configurations can be employed. For example, as illustrated in FIG. 14, the peripheral pixel region 5 may include a plurality of specific pixel groups 25. In this case, a pattern of an area occupied by the light receiving pixels 2B included in the specific pixel group 25 may include two or more types of patterns. FIG. 14 illustrates a case where 10 specific pixel groups 25 are provided in the peripheral pixel region 5, and the pattern of the area occupied by the light receiving pixels 2B includes three types of patterns, large, medium, and small.

With such a configuration, for example, it is possible for a specific pixel group 25 (hereinafter, also referred to as “specific pixel group 25A”) that is larger in the area occupied by the light receiving pixels 2B to increase the total amount of charges generated by the light receiving pixels 2B, simulate the spread of charges from an effective pixel 2A with higher incident light intensity to surrounding effective pixels 2A, and obtain color mixing parameters a₀₀, a₀₁, a₀₂ . . . for correcting the output signal of the effective pixel 2A with higher incident light intensity. Furthermore, for example, it is possible for a specific pixel group 25 (hereinafter, also referred to as “specific pixel group 25B”) that is smaller in the area occupied by the light receiving pixels 2B to reduce the total amount of charges generated by the light receiving pixels 2B, simulate the spread of charges from an effective pixel 2A with lower incident light intensity to surrounding effective pixels 2A, and obtain the color mixing parameters a₀₀, a₀₁, a₀₂ . . . for correcting output signal of the effective pixel 2A with lower incident light intensity. Furthermore, for example, it is possible for a specific pixel group 25 (hereinafter also referred to “specific pixel group 25C”) ranked between the specific pixel groups 25A and 25B in terms of the area occupied by the light receiving pixels 2B to obtain color mixing parameters a₀₀, a₀₁, a₀₂ . . . for correcting the output signal of an effective pixel 2A with moderate incident light intensity.

Furthermore, in this case, the color mixing parameter generation unit 28 generates respective color mixing parameters A₁=[a₀₀, a₀₁, a₀₂ . . . ], A₂=[a₀₀, a₀₁, a₀₂ . . . ], and A₃=[a₀₀, a₀₁, a₀₂ . . . ] . . . for the specific pixel groups 25A, 25B, and 25C.

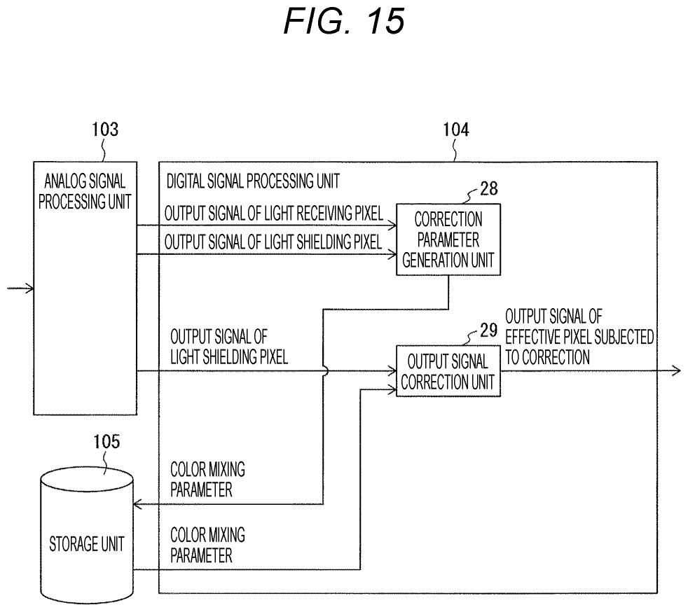

Moreover, the output signal correction unit 29 selects, according to the magnitude of each output signal to be corrected, a color mixing parameter Aᵢ (i is greater than or equal to 1) used to correct the output signal from among the plurality of color mixing parameters A₁, A₂, A₃ . . . generated by the color mixing parameter generation unit 28. As an example, for each output signal to be corrected, the color mixing parameter Aᵢ in which the total value of the output signals of the light receiving pixels 2B of the specific pixel group 25 used to generate the color mixing parameter is closest to the value of the output signal to be corrected is selected from among the plurality of color mixing parameters A₁, A₂, A₃ . . . . It is therefore possible to more appropriately correct each of the output signal of the effective pixel 2A with higher incident light intensity, the output signal of the effective pixel 2A with lower incident light intensity, and the output signal of the effective pixel 2A with moderate incident light intensity.
(4) Furthermore, in the first embodiment, the example has been described where the color mixing parameter generation unit 28 generates the color mixing parameters a₀₀, a₀₁, a₀₂ . . . in real time when the image of the subject is captured, but other configurations can be employed. For example, as illustrated in FIG. 15, the color mixing parameter generation unit 28 may generate the color mixing parameters a₀₀, a₀₁, a₀₂ . . . before image capturing. In this case, the color mixing parameters a₀₀, a₀₁, a₀₂ . . . generated by the color mixing parameter generation unit 28 are stored in the storage unit 105. Furthermore, the output signal correction unit 29 corrects the respective output signals of the effective pixels 2A using the color mixing parameters a₀₀, a₀₁, a₀₂ . . . stored in the storage unit 105.

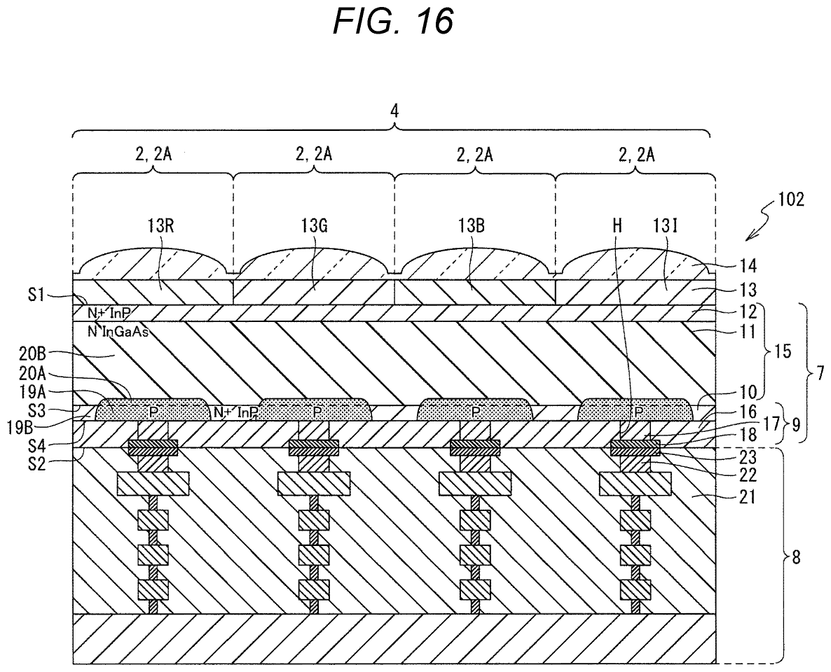

As an example, in each of a plurality of use environments (the temperature of the light receiving element 102 and the intensity of light incident on light receiving pixel 2B), a plurality of color mixing parameters A₁=[a₀₀, a₀₁, a₀₂ . . . ], A₂=[a₀₀, a₀₁, a₀₂ . . . ], A₃=[a₀₀, a₀₁, a₀₂ . . . ] . . . is generated on the basis of the output signals output from the light receiving pixel 2B and the light shielding pixels 2C. Furthermore, the plurality of color mixing parameters a₀₀, a₀₁, a₀₂ . . . generated by the color mixing parameter generation unit 28 is stored in the storage unit 105 for each combination of temperature and light intensity. Moreover, the output signal correction unit 29 selects, for each output signal to be corrected, a color mixing parameter Aᵢ closest to the combination of the temperature of the light receiving element 102 at the time of imaging and the intensity of light incident on the effective pixel 2A to be corrected from among the plurality of color mixing parameters A₁, A₂, A₃ . . . stored in the storage unit 105. Then, each of the output signals of the effective pixels 2A is corrected using the selected color mixing parameter Aᵢ. It is therefore possible to select a more appropriate color mixing parameter Aᵢ according to the use environment, and more appropriately enhance the image quality of the captured image.
(5) Furthermore, in the first embodiment, the example has been described where nothing is stacked on the back surface S1 of the second contact layer 12 in the effective pixel region 4, but other configurations can be employed. For example, as illustrated in FIG. 16, either or both of a color filter 13 and a microlens 14 may be stacked on the back surface S1 of the second contact layer 12. FIG. 16 illustrates a case where both the color filter 13 and the microlens 14 are stacked in this order.

The color filter 13 is arranged at a position coincident with each of the plurality of pixels 2 in plan view. That is, one color filter 13 is formed for each pixel 2. The color filter 13 includes, for example, a red filter 13R, a green filter 13G, a blue filter 13B, and an IR filter 131. Then, each of the color filters 13 transmits light having a predetermined wavelength and causes the transmitted light to enter the photoelectric conversion layer 11. With such a configuration, it is possible to prevent light having a wavelength other than the predetermined wavelength from entering the photoelectric conversion layer 11 and prevent optical color mixing.

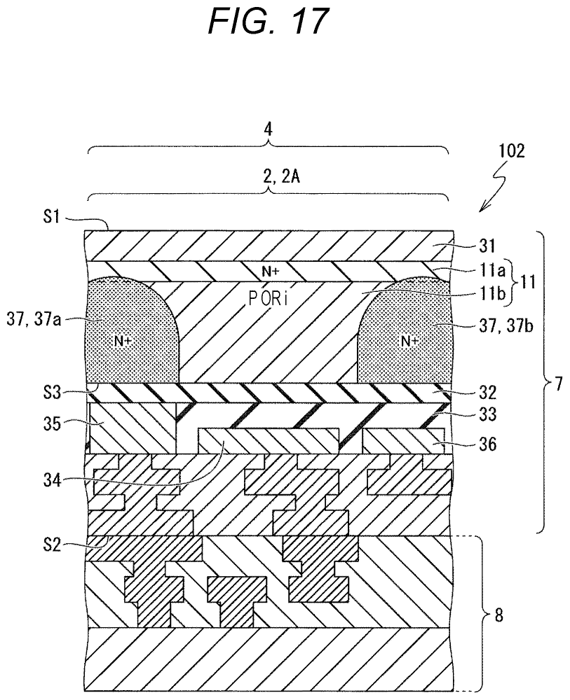

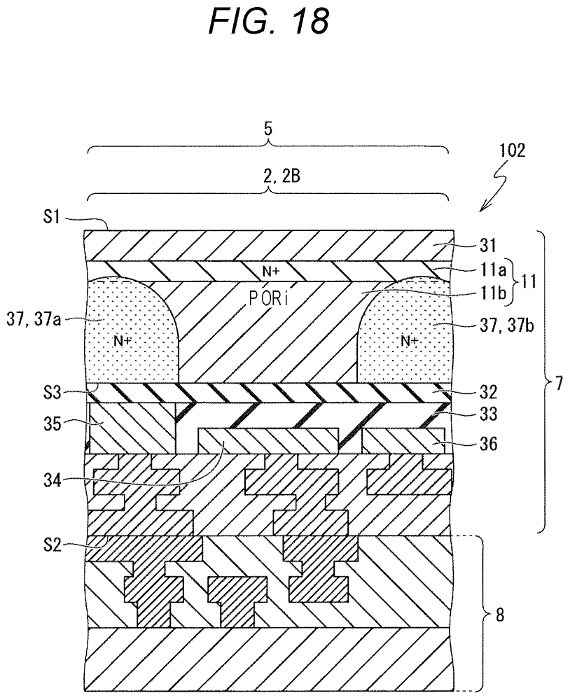

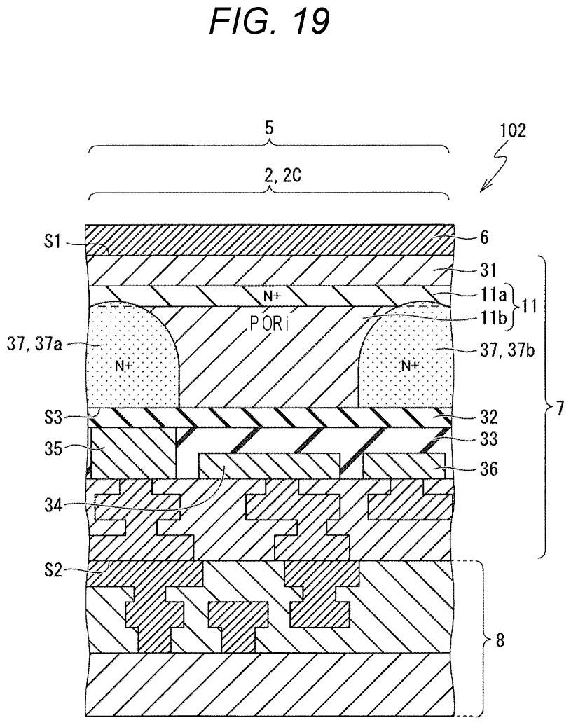

The microlens 14 is arranged at a position coincident with each of the plurality of pixels 2 in plan view. That is, one microlens 14 is formed for each pixel 2. Then, each of the microlenses 14 condenses incident light (image light) from a subject and causes the condensed incident light to enter each part (part coincident in position with the microlens 14) of the photoelectric conversion layer 11. With such a configuration, it is possible to prevent light incident on the microlens 14 of a certain pixel 2 from entering a part of the photoelectric conversion layer 11 corresponding to another adjacent pixel 2 and prevent optical color mixing.
(6) Furthermore, the configuration of the element substrate 7 is not limited to the configuration illustrated in FIG. 3, and for example, the configurations illustrated in FIGS. 17, 18, and 19 can also be employed. FIG. 17 is a diagram illustrating a cross-sectional structure of an element substrate 7 in the effective pixel region 4. Furthermore, FIG. 18 is a diagram illustrating a cross-sectional configuration of a light receiving pixel 2B in the peripheral pixel region 5. Furthermore, FIG. 19 is a diagram illustrating a cross-sectional configuration of a light shielding pixel 2C in the peripheral pixel region 5. In the effective pixel region 4, as illustrated in FIG. 17, the element substrate 7 includes a photoelectric conversion layer 11, an upper electrode 31 arranged on the light incident surface of the photoelectric conversion layer 11, a first insulating film 32 arranged on the surface S3 of the photoelectric conversion layer 11, a second insulating film 33 arranged on a surface of the first insulating film 32 adjacent to a readout circuit substrate 8, and a storage electrode 34, a lower electrode 35, and a shield electrode 36 arranged in the second insulating film 33 separately from each other. Furthermore, the photoelectric conversion layer 11 includes an N+ layer 11a and a P layer or a Non-doped layer (hereinafter also referred to as “i layer”) 11b. Here, the N+ layer 11a is arranged in contact with the upper electrode 31, and the P layer or the i layer 11b is arranged in contact with the first insulating film 32. Furthermore, the first insulating film 32 has a potential capable of accumulating and transferring charges (for example, holes) resulting from the photoelectric conversion in the photoelectric conversion layer 11.

Furthermore, in the photoelectric conversion layer 11, an impurity ion diffusion region 37 (first diffusion region 37a) covering the lower electrode 35 and an impurity ion diffusion region 37 (second diffusion region 37b) covering the shield electrode 36 are formed. The first diffusion region 37a and the second diffusion region 37b are each a region where N+ impurity ions are diffused. With such a configuration, in the element substrate 7 illustrated in FIG. 17, when holes resulting from the photoelectric conversion in the photoelectric conversion layer 11 flow into the first diffusion region 37a or the second diffusion region 37b, the holes are recombined with electrons in the first diffusion region 37a or the second diffusion region 37b. It is therefore possible to prevent holes from flowing from the first diffusion region 37a to the lower electrode 35.

Furthermore, in the peripheral pixel region 5, the element substrate 7 includes the light shielding film 6 having an opening as the outermost layer as illustrated in FIG. 4 in addition to the layers similar to those in the effective pixel region 4 to form the light receiving pixel 2B, the light shielding pixel 2C, and the specific pixel group 25. Furthermore, as illustrated in FIGS. 18 and 19, the impurity ion diffusion regions 37 (the first diffusion region 37a and the second diffusion region 37b) corresponding to the light receiving pixel 2B and the light shielding pixel 2C of the specific pixel group 25 is lower in N-type impurity concentration than the impurity ion diffusion region 37 corresponding to the effective pixel 2A located in the effective pixel region 4. Here, the impurity ion diffusion region 37 and the P layer or the i layer 11b correspond to the “contact layer”, the impurity ion diffusion region 37 corresponds to the “first conductivity type region”, the P layer or the i layer 11b corresponds to the “second conductivity type region”, the N type corresponds to the “first conductivity type”, and the P type corresponds to the “second conductivity type”.
(7) Furthermore, the present technology can be applied to, not only the imaging device 100 described above, but also any light detection device that measures a distance, such as a ranging sensor also known as time of flight (ToF) sensor. The ranging sensor is a sensor that emits irradiation light toward an object, detects reflected light that is the irradiation light reflected off a surface of the object, and calculates a distance to the object on the basis of a flight time from the emission of the irradiation light to the reception of the reflected light.

Note that the present disclosure may also have the following configurations.
(1) A light receiving element including:
a plurality of pixels having a common photoelectric conversion layer including a compound semiconductor; and
a contact layer arranged on a surface of the photoelectric conversion layer opposite to a light incident surface, in which
the contact layer includes a plurality of first conductivity type regions formed on a one-to-one basis with respect to a plurality of the pixels, and a second conductivity type region that is a region other than the first conductivity type region, and
a peripheral pixel region located outside an effective pixel region in a pixel region where the pixels are arranged includes a specific pixel group including a light receiving pixel and a light shielding pixel arranged to surround the light receiving pixel, the first conductivity type region corresponding to the light receiving pixel and the light shielding pixel of the specific pixel group being lower in concentration of a first conductivity type impurity than the first conductivity type region corresponding to an effective pixel located in the effective pixel region.
(2) The light receiving element according to the above (1) further including:
a wiring layer arranged on a surface of the contact layer opposite to a surface of the photoelectric conversion layer, in which
the wiring layer includes an electrode electrically connected to the first conductivity type region, and
concentration distribution of the first conductivity type impurity in the first conductivity type region on a straight-line extending from an interface between the first conductivity type region and the electrode toward the light incident surface of the photoelectric conversion layer has a flat region from the interface to a predetermined depth in an extending direction of the straight-line, an average concentration of the flat region of the concentration distribution in the first conductivity type region corresponding to the light receiving pixel and the light shielding pixel of the specific pixel group being lower than an average concentration of the flat region of the concentration distribution in the first conductivity type region corresponding to the effective pixel located in the effective pixel region.
(3) The light receiving element according to the above (1) or (2), in which
the specific pixel group includes the light receiving pixel including one light receiving pixel and the light shielding pixel including a plurality of the light shielding pixels surrounding the one light receiving pixel, or includes the light receiving pixel including two or more light receiving pixels arranged in a two-dimensional array and the light shielding pixel including a plurality of the light shielding pixels surrounding the two or more light receiving pixels.
(4) The light receiving element according to the above (3), in which
the peripheral pixel region includes a plurality of the specific pixel groups, and has two or more types of patterns of an area occupied by the light receiving pixel included in each of the specific pixel group.
(5) The light receiving element according to any one of the above (1) to (3), in which
the peripheral pixel region includes an OPB pixel used to obtain a reference signal for optical black level, the OPB pixel being different from the light receiving pixel and the light shielding pixel, and the first conductivity type region corresponding to the OPB pixel is identical in concentration of the first conductivity type impurity to the first conductivity type region corresponding to the effective pixel.
(6) The light receiving element according to any one of the above (1) to (5),
in which the compound semiconductor includes any one of InGaAs, InGaN, InAlN, InAsSb, InAs, InSb, and HgCdTe.
(7) A light detection device including:
a light receiving element including a plurality of pixels having a common photoelectric conversion layer including a compound semiconductor, and a contact layer arranged on a surface of the photoelectric conversion layer opposite to a light incident surface, the contact layer including a plurality of first conductivity type regions formed on a one-to-one basis with respect to a plurality of the pixels, and a second conductivity type region that is a region other than the first conductivity type region, a peripheral pixel region located outside an effective pixel region in a pixel region where the pixels are arranged including a specific pixel group including a light receiving pixel and a light shielding pixel arranged to surround the light receiving pixel, the first conductivity type region corresponding to the light receiving pixel and the light shielding pixel of the specific pixel group being lower in concentration of a first conductivity type impurity than the first conductivity type region corresponding to effective pixels located in the effective pixel region;
a color mixing parameter generation unit that generates, on the basis of output signals of the light receiving pixel and the light shielding pixel of the specific pixel group, a color mixing parameter used to reduce an impact of charges moved from another one of the effective pixels from an output signal of each of the effective pixels located in the effective pixel region of the light receiving element; and
an output signal correction unit that corrects the output signal of each of the effective pixels in accordance with the color mixing parameter generated by the color mixing parameter generation unit.
(8) The light detection device according to the above (7), in which the color mixing parameter generation unit sets a range of the light shielding pixel used to generate the color mixing parameter according to a use environment.
(9) The light detection device according to the above (8),
in which in a case where a temperature of the light receiving element is greater than or equal to a predetermined threshold, the color mixing parameter generation unit widens the range of the light shielding pixels used to generate the color mixing parameter as compared with a case where the temperature of the light receiving element is less than the predetermined threshold.
(10) The light detection device according to the above (8) or (9),
in which in a case where a voltage applied to the photoelectric conversion layer is less than or equal to a predetermined threshold, the color mixing parameter generation unit widens the range of the light shielding pixel used to generate the color mixing parameter as compared with a case where the voltage applied to the photoelectric conversion layer is greater than the predetermined threshold.
(11) The light detection device according to the above (7),
in which the peripheral pixel region includes a plurality of the specific pixel groups, and has two or more types of patterns of an area occupied by the light receiving pixel included in the specific pixel group,
the color mixing parameter generation unit generates the color mixing parameter for each of the specific pixel groups, and
the output signal correction unit selects, for each output signal to be corrected, the color mixing parameter used to correct the output signal according to magnitude of the output signal from among a plurality of the color mixing parameters generated by the color mixing parameter generation unit.
(12) The light detection device according to any one of the above (7) to (11),
in which the color mixing parameter generation unit calculates a ratio of magnitude of the output signal of the light shielding pixel to magnitude of the output signal of the light receiving pixel as the color mixing parameter.
(13) The light detection device according to any one of the above (7) to (12), further including:
a storage unit that stores the color mixing parameter generated by the color mixing parameter generation unit,
in which the output signal correction unit corrects the output signal of each of the effective pixels using the color mixing parameter stored in the storage unit.

### REFERENCE SIGNS LIST

2 Pixel
2A Effective pixel
2B Light receiving pixel
2C Light shielding pixel
2D OPB pixel
3 Pixel region
4 Effective pixel region
5 Peripheral pixel region
6 Light shielding film
7 Element substrate
8 Readout circuit substrate
9 Wiring layer
10 First contact layer
11 Photoelectric conversion layer
12 Second contact layer
15 Semiconductor layer
16 Interlayer insulating film
17 Electrode
18 Connection layer
19A First conductivity type region
19B Second conductivity type region
20A First conductivity type region
20B Second conductivity type region
21 Interlayer insulating film
22 Readout electrode
23 Connection layer
25, 25A, 25B, 25C Specific pixel group
26 Concentration distribution
27 Connection layer
28 Color mixing parameter generation unit
29 Output signal correction unit
30 Region
31 Upper electrode
32 First insulating film
33 Second insulating film
34 Storage electrode
35 Lower electrode
36 Shield electrode
37 Impurity ion diffusion region
37a First diffusion region
37b Second diffusion region
100 Imaging device
101 Camera lens
102 Light receiving element
103 Analog signal processing unit
104 Digital signal processing unit
105 Storage unit

What is claimed is:

1. A light receiving element comprising:
a plurality of pixels having a common photoelectric conversion layer including a compound semiconductor; and
a contact layer arranged on a surface of the photoelectric conversion layer opposite to a light incident surface,
wherein the contact layer includes a plurality of first conductivity type regions formed on a one-to-one basis with respect to a plurality of the pixels, and a second conductivity type region that is a region other than the first conductivity type region, and
a peripheral pixel region located outside an effective pixel region in a pixel region where the pixels are arranged includes a specific pixel group including a light receiving pixel and a light shielding pixel arranged to surround the light receiving pixel, the first conductivity type region corresponding to the light receiving pixel and the light shielding pixel of the specific pixel group being lower in concentration of a first conductivity type impurity than the first conductivity type region corresponding to an effective pixel located in the effective pixel region.

2. The light receiving element according to claim 1, further comprising:
a wiring layer arranged on a surface of the contact layer opposite to a surface of the photoelectric conversion layer,
wherein the wiring layer includes an electrode electrically connected to the first conductivity type region, and
concentration distribution of the first conductivity type impurity in the first conductivity type region on a straight-line extending from an interface between the first conductivity type region and the electrode toward the light incident surface of the photoelectric conversion layer has a flat region from the interface to a predetermined depth in an extending direction of the straight-line, an average concentration of the flat region of the concentration distribution in the first conductivity type region corresponding to the light receiving pixel and the light shielding pixel of the specific pixel group being lower than an average concentration of the flat region of the concentration distribution in the first conductivity type region corresponding to the effective pixel located in the effective pixel region.

3. The light receiving element according to claim 1,
wherein the specific pixel group includes the light receiving pixel including one light receiving pixel and the light shielding pixel including a plurality of the light shielding pixels surrounding the one light receiving pixel, or includes the light receiving pixel including two or more light receiving pixels arranged in a two-dimensional array and the light shielding pixel including a plurality of the light shielding pixels surrounding the two or more light receiving pixels.

4. The light receiving element according to claim 3,
wherein the peripheral pixel region includes a plurality of the specific pixel groups, and has two or more types of patterns of an area occupied by the light receiving pixel included in each of the specific pixel group.

5. The light receiving element according to claim 1,
wherein the peripheral pixel region includes an OPB pixel used to obtain a reference signal for optical black level, the OPB pixel being different from the light receiving pixel and the light shielding pixel, and the first conductivity type region corresponding to the OPB pixel is identical in concentration of the first conductivity type impurity to the first conductivity type region corresponding to the effective pixel.

6. The light receiving element according to claim 1,
wherein the compound semiconductor includes any one of InGaAs, InGaN, InAlN, InAsSb, InAs, InSb, and HgCdTe.

7. A light detection device comprising:
a light receiving element including a plurality of pixels having a common photoelectric conversion layer including a compound semiconductor, and a contact layer arranged on a surface of the photoelectric conversion layer opposite to a light incident surface, the contact layer including a plurality of first conductivity type regions formed on a one-to-one basis with respect to a plurality of the pixels, and a second conductivity type region that is a region other than the first conductivity type region, a peripheral pixel region located outside an effective pixel region in a pixel region where the pixels are arranged including a specific pixel group including a light receiving pixel and a light shielding pixel arranged to surround the light receiving pixel, the first conductivity type region corresponding to the light receiving pixel and the light shielding pixel of the specific pixel group being lower in concentration of a first conductivity type impurity than the first conductivity type region corresponding to effective pixels located in the effective pixel region;
a color mixing parameter generation unit that generates, on a basis of output signals of the light receiving pixel and the light shielding pixel of the specific pixel group, a color mixing parameter used to reduce an impact of charges moved from another one of the effective pixels from an output signal of each of the effective pixels located in the effective pixel region of the light receiving element; and
an output signal correction unit that corrects the output signal of each of the effective pixels in accordance with the color mixing parameter generated by the color mixing parameter generation unit.

8. The light detection device according to claim 7,
wherein the color mixing parameter generation unit sets a range of the light shielding pixel used to generate the color mixing parameter according to a use environment.

9. The light detection device according to claim 8,
wherein in a case where a temperature of the light receiving element is greater than or equal to a predetermined threshold, the color mixing parameter generation unit widens the range of the light shielding pixel used to generate the color mixing parameter as compared with a case where the temperature of the light receiving element is less than the predetermined threshold.

10. The light detection device according to claim 8,
wherein in a case where a voltage applied to the photoelectric conversion layer is less than or equal to a predetermined threshold, the color mixing parameter generation unit widens the range of the light shielding pixel used to generate the color mixing parameter as compared with a case where the voltage applied to the photoelectric conversion layer is greater than the predetermined threshold.

11. The light detection device according to claim 7,
wherein the peripheral pixel region includes a plurality of the specific pixel groups, and has two or more types of patterns of an area occupied by the light receiving pixel included in the specific pixel group,
the color mixing parameter generation unit generates the color mixing parameter for each of the specific pixel groups, and
the output signal correction unit selects, for each output signal to be corrected, the color mixing parameter used to correct the output signal according to magnitude of the output signal from among a plurality of the color mixing parameters generated by the color mixing parameter generation unit.

12. The light detection device according to claim 7, wherein
the color mixing parameter generation unit calculates a ratio of magnitude of the output signal of the light shielding pixel to magnitude of the output signal of the light receiving pixel as the color mixing parameter.

13. The light detection device according to claim 7, further comprising:
a storage unit that stores the color mixing parameter generated by the color mixing parameter generation unit, wherein
the output signal correction unit corrects the output signal of each of the effective pixels using the color mixing parameter stored in the storage unit.
